(19) United States
(12) Patent Application Publication
(10) Pub. No.: US 2012/0097831 A1
(43) Pub. Date: Apr. 26, 2012

(54) DISPLAY DEVICE CASE, STAND AND ACCESSORY SYSTEM

(75) Inventors: Laate Leon Olukotun, Hopewell, NJ (US); Hyun Yoo, Grand Rapids, MI (US); Garrett Neville Brooks, Baltimore, MD (US)

(73) Assignee: Lollygig LLC, Princeton, NJ (US)

(21) Appl. No.: 13/278,226

(22) Filed: Oct. 21, 2011

Related U.S. Application Data
(60) Provisional application No. 61/455,477, filed on Oct. 21, 2010.

(51) Int. Cl. H05K 7/00

(52) U.S. Cl. 248/688; 248/682

(57) ABSTRACT

A sleeve system for a rectangular electronic device enables adjustment of the electronic device from landscape orientation, wherein the longer side of the electronic device is horizontal, to portrait orientation, wherein the longer side of the electronic device is vertical, while the electronic device is engaged with the sleeve system. The sleeve system may be used on a user's hand, or with an accessory such as a tabletop stand, wall hook, garment or headrest cover for a seat. A rail may be provided to support multiple instances of the wall hook.

### CROSS-REFERENCE TO RELATED APPLICATIONS

This application claims priority from U.S. provisional patent application Ser. No. 61/455,477, filed Oct. 21, 2010, which is hereby incorporated by reference in its entirety.

### BACKGROUND OF THE INVENTION

The present invention relates to protective coverings and support mechanisms for a portable electronic device.

In the last twenty years personal electronic devices have gained in popularity throughout the world. First desktop computers made their way into people's homes along with an assortment of peripheral devices and accessories. Then laptop computers brought a new level of portability to first the business world and then to consumers. In the last few years devices have become increasingly sophisticated in their technological advancement—including the latest smartphones and tablet devices.

While the technological capabilities of these devices—especially tablet devices and smartphones—have grown in their digital sophistication, a new class of physical accessories have emerged to accommodate shortcomings in these devices.

Some examples of such physical accessories are discussed below.

Modulr LLC recently introduced a modular system of product accessories for use with the iPad, including an iPad case+cover, an iPad shoulder strap, a universal swing arm, an iPad slim wall mount and an iPad quick stand for tabletop use. The Modulr LLC system focuses on a specific attachment method to the display device. See www.modulrcase.com/index.php.

FIG. 1 shows an iPad Glove by Andrew Donaho, that is made of leather and fabric, and attaches to an iPad using stretchy corner bands (there are both 2-corner and 4-corner versions of the holder). The iPad Glove allows a user to hold up the device easily with just one hand, leaving the other free to point out app features or otherwise gesture.” The iPad Glove is sold as the X-Band by TKO Solutions. See www.tuaw.com/2010/04/24/voices-that-matter-iphone-one-handed-ipad-holder/.

FIGS. 2A and 2B show a PadStand that is a simple connection system developed to enable iPad users to easily hang their device in either a horizontal or vertical position. A small square, shown in FIG. 2A, is firmly attached to the back of the iPad. Another “male” slot, shown in FIG. 2B, is then placed on a vertical surface (e.g., a refrigerator door or a wall). When the small square is aligned with the male slot, the iPad can hang in a mounted position. This works just as easily in either a horizontal or vertical orientation.

FIG. 3 shows a wooden iPad Stand produced by a Dutch company. This stand offers the simplest of adjustments—either the iPad can sit in a horizontal position or sit in a vertical position. See www.woodenipadstands.com/press/.

These physical accessories have the following shortcomings:
they oftentimes lack simple protection from the elements,
they have few specific affordances allowing for effective human computer interaction,
they have few hands-free methods for viewing and manipulation, and
they lack the ability to adjust the orientation of a display device without the need of disengaging or removing a user's hand from the display device case and system.

### SUMMARY OF THE INVENTION

In accordance with an aspect of this invention, there is provided a system for displaying a display device comprising a housing with a means for receiving the display device and a pocket/sleeve on a back side of the housing, the pocket sleeve having a teeth opening shape, wherein the teeth opening shape allows a user to have a plurality of positions within that pocket to enable the user to rotate the device from a horizontal to a vertical view without removing their hand from the pocket/sleeve.

It is not intended that the invention be summarized here in its entirety. Rather, further features, aspects and advantages of the invention are set forth in or are apparent from the following description and drawings.

### BRIEF DESCRIPTION OF THE DRAWINGS

FIG. 1 shows a prior art glove for allowing a user to hold an electronic device with one hand;

FIGS. 2A and 2B show a prior art component for attaching to a device, and another component that attaches to a wall and receives the first component;

FIG. 3 shows a prior art stand for an electronic device;

FIGS. 4A-4C show front views of different embodiments of the present invention;

FIG. 5 shows a front view of an embodiment of the present invention used with an electronic device;

FIG. 6A shows a back view of an embodiment of the present invention used with an electronic device in landscape orientation;

FIG. 6B shows a back view of an embodiment of the present invention used with an electronic device in portrait orientation;

FIGS. 7A and 7B show another embodiment of the present invention;

FIG. 8 shows a front three-dimensional view of an embodiment of the present invention used with an electronic device;

FIG. 9A shows a front view of an embodiment of the present invention used with an electronic device in landscape orientation;

FIG. 9B shows a front view of an embodiment of the present invention used with an electronic device in portrait orientation;

FIG. 10A shows a back view of an embodiment of the present invention used with an electronic device in landscape orientation;

FIG. 10B shows a back view of an embodiment of the present invention used with an electronic device in portrait orientation;

FIG. 11 shows a three-dimensional view of an embodiment of the present invention;

FIG. 12A shows a side view of an embodiment of the present invention used with an electronic device in landscape orientation;

FIG. 12B shows a side view of an embodiment of the present invention used with an electronic device in portrait orientation;

FIG. 13A shows a three-dimensional view of an embodiment of the present invention used with an electronic device in landscape orientation;

FIG. 13B shows a three-dimensional view of an embodiment of the present invention used with an electronic device in portrait orientation;

FIG. 14A shows a three-dimensional view of an embodiment of the present invention;

FIG. 14B shows a three-dimensional view of an embodiment of the present invention used with electronic devices;

FIG. 14C shows a three-dimensional view of an embodiment of the present invention used with picture frames;

FIG. 15A shows a three-dimensional back view of an embodiment of the present invention;

FIG. 15B shows a three-dimensional front view of an embodiment of the present invention;

FIG. 16A shows a front view of an embodiment of the present invention;

FIG. 16B shows a side view of an embodiment of the present invention; and

FIG. 17 shows a three-dimensional back view of an embodiment of the present invention.

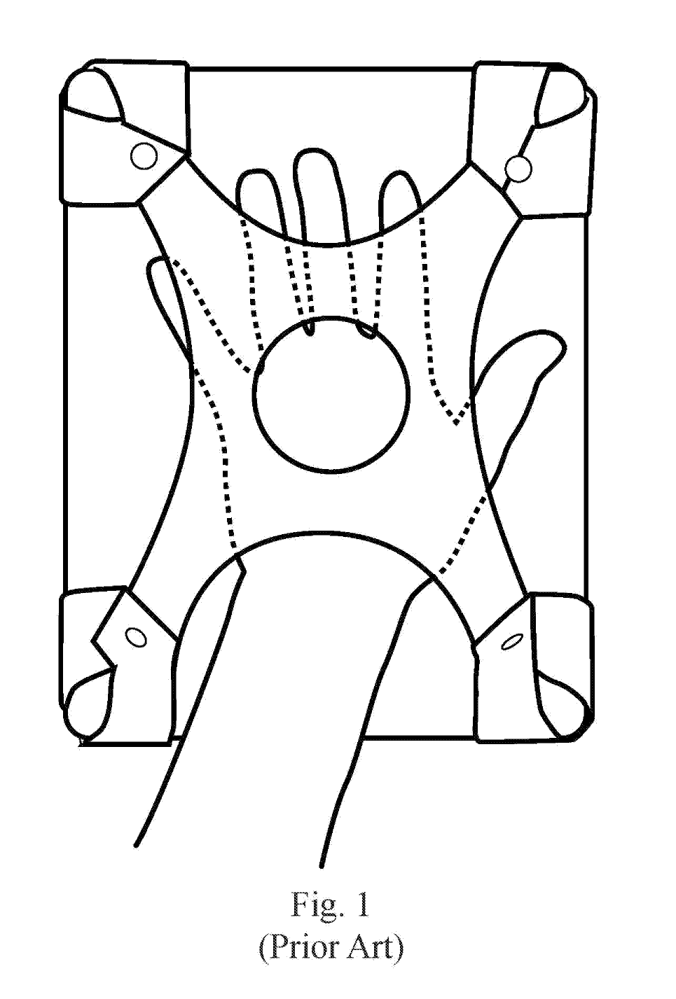

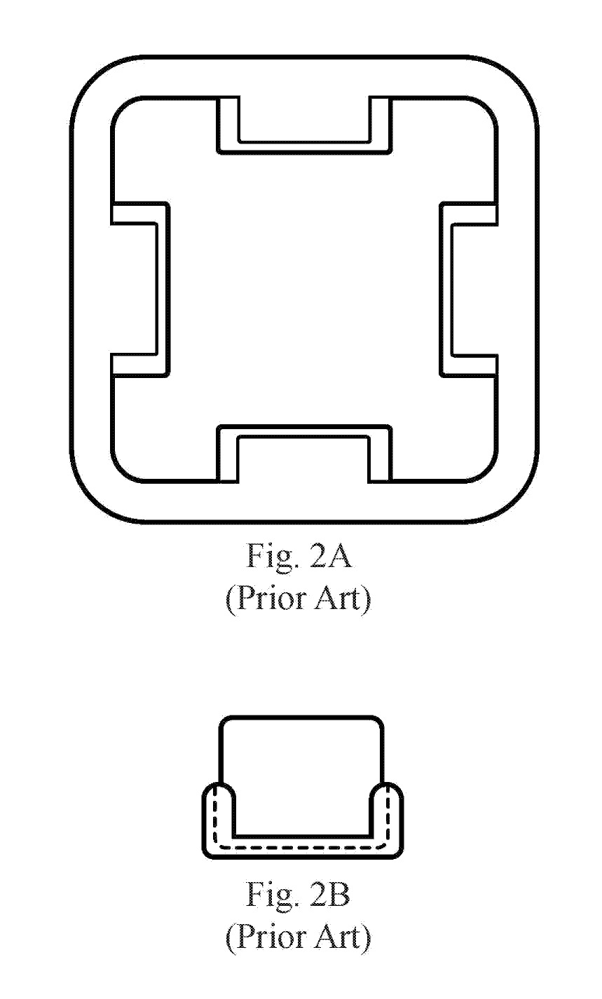

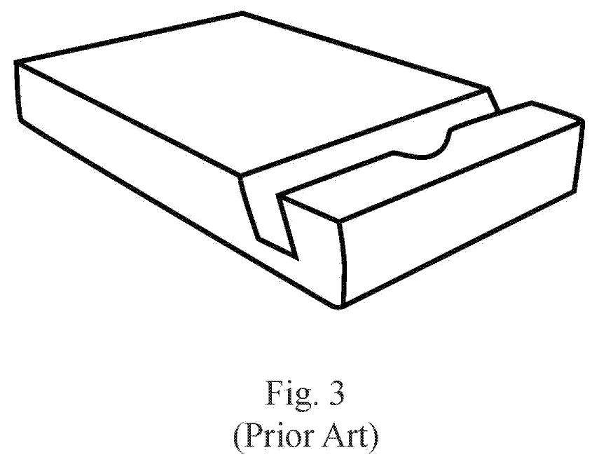

### DETAILED DESCRIPTION

Embodiments of a sleeve system for a rectangular electronic device enable adjustment of the electronic device from landscape orientation, wherein the longer side of the electronic device is horizontal, to portrait orientation, wherein the longer side of the electronic device is vertical, while the electronic device is engaged with the sleeve system. The sleeve system may be used on a user's hand, or with an accessory such as a tabletop stand, wall hook, garment or headrest cover for a seat. A rail may be provided to support multiple instances of the wall hook.

An embodiment of the present invention directed to a handheld sleeve system will now be described.

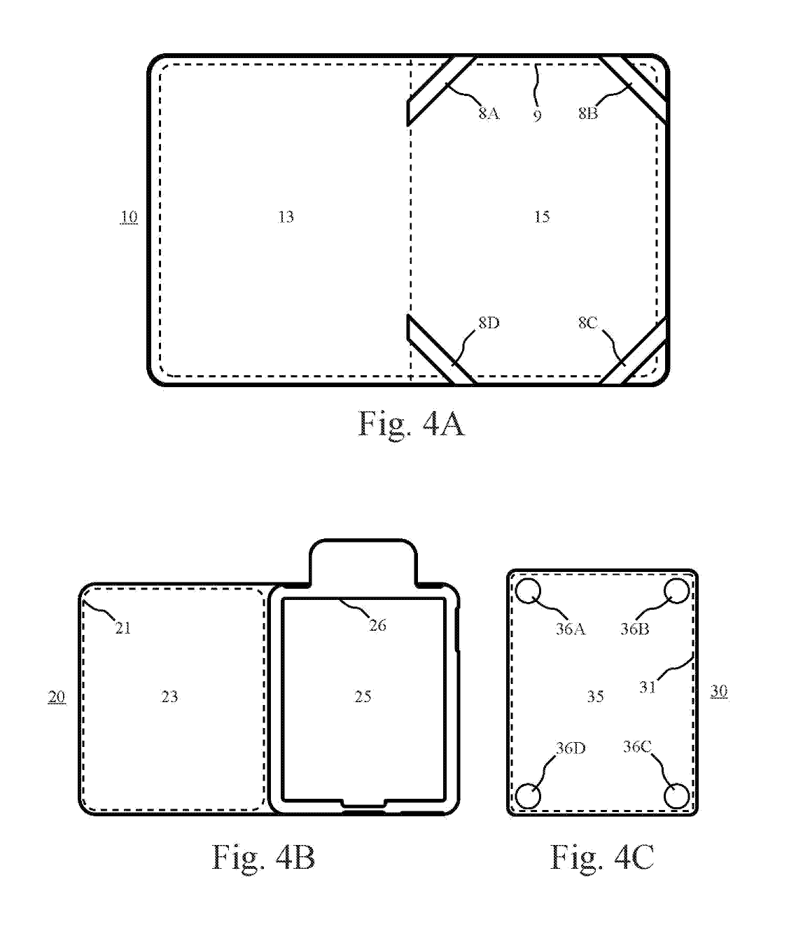

FIGS. 4A-4C show front views of different embodiments of the present invention.

FIG. 4A shows sleeve system 10 having front panel 15 extending into flap 13, with stitching 9 around its perimeter. Flap 13 opens to reveal an electronic device (not shown), and closes to protect the electronic device when the electronic device is being carried. Elastic bands 8A, 8B, 8C, 8D are located at the corners of front panel 10, for retaining the corners of a rectangular electronic device (not shown) such as an iPad.

FIG. 4B shows sleeve system 20 having front panel 25 extending into flap 23, with stitching 21 around its edge, and vertical edge 26 around three sides of front panel 25 that serves to frame an electronic device (not shown). Flap 23 functions in similar manner as flap 13.

FIG. 4C shows sleeve system 30 having front panel 35, and no flap. Front panel 35 has stitching 31 around its perimeter. The corners of front panel 35 have respective fasteners 36A, 36B, 36C, 36D such as circles of hook fasteners that mate with loop fasteners disposed at the corners of an electronic device (not shown).

In other embodiments, sleeve system 10 may have a pocket that receives the display device, as it is slid into the pocket. Sleeve system 10 may be attached or connected to the display device with, but not limited to: a strong adhesive, buttons, Velcro, snaps, zipper, magnets, or appropriate adhesive. Sleeve system 10 may have a zipper around its perimeter so that the flap can be zipped closed when the electronic device is not being used. Sleeve system 10 may also have handles and/or a shoulder strap and/or various internal and external pockets.

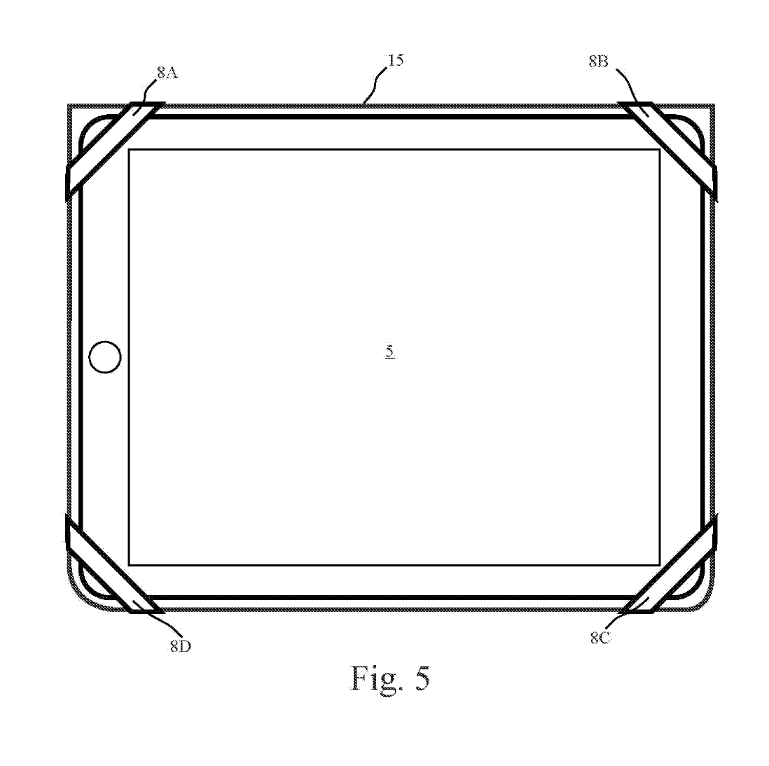

FIG. 5 shows a front view of sleeve system 10 used with electronic device 5.

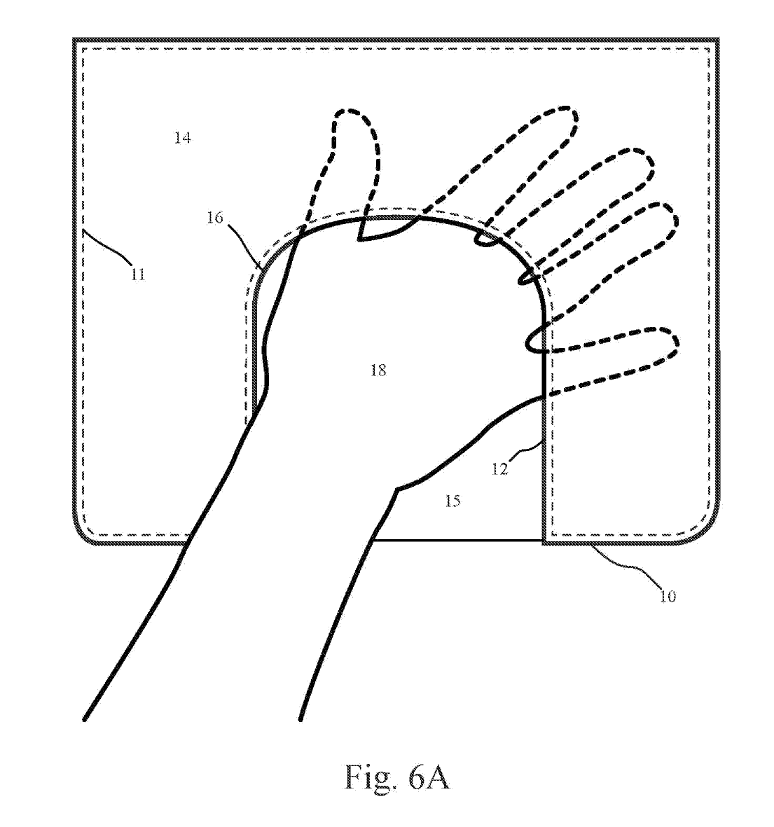

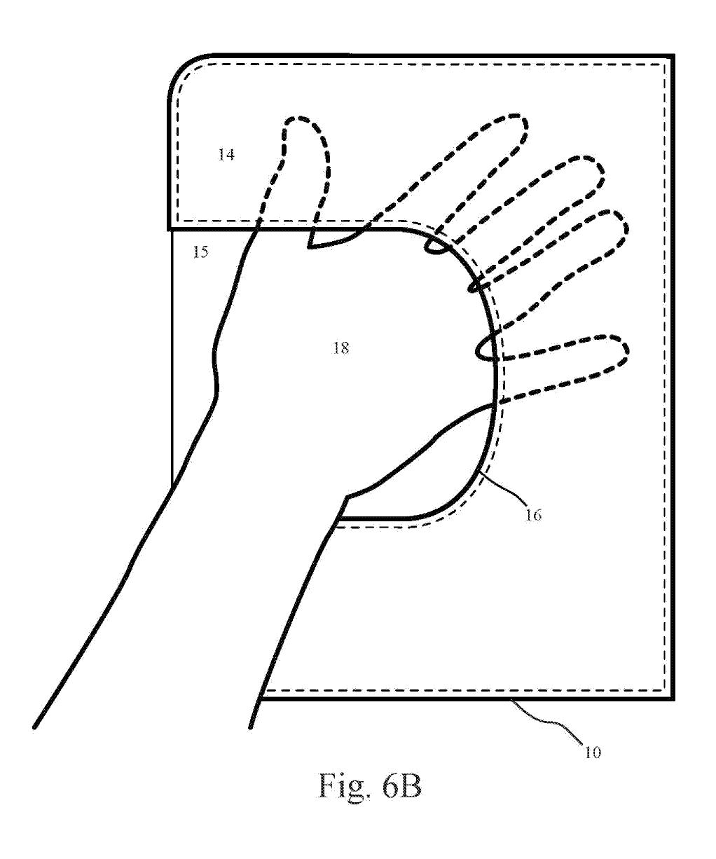

FIG. 6A shows a back view of sleeve system 10 used with electronic device 5 (not shown) in landscape orientation. Back panel 14 has stitching 11 around its perimeter, and U-shaped cutout 16 along one side. Hand 18 is inserted into pocket 12 formed between back panel 14 and front panel 15.

FIG. 6B shows a back view of sleeve system 10 used with electronic device 5 (not shown) in portrait orientation.

The front and back panels of sleeve system 10 are made of a flexible material, such as neoprene, ballistic nylon and so on.

It will be appreciated that the user can readily slide his or her hand inside pocket 12, thereby turning the electronic device from landscape orientation to portrait orientation and vice-versa while keeping his or her hand inside pocket 12. This is particularly convenient as the material being displayed on electronic device 5 switches from portrait to landscape orientation and vice-versa.

It will be appreciated that sleeve systems 20 and 30 have back constructions similar to that shown for sleeve system 10. For brevity, only sleeve system 10 will be discussed in the remainder of this application, but it should be understood that sleeve systems 20 or 30 can be used in place of sleeve system 10.

An embodiment of the present invention directed to a tabletop stand for use with sleeve system 10 will now be described.

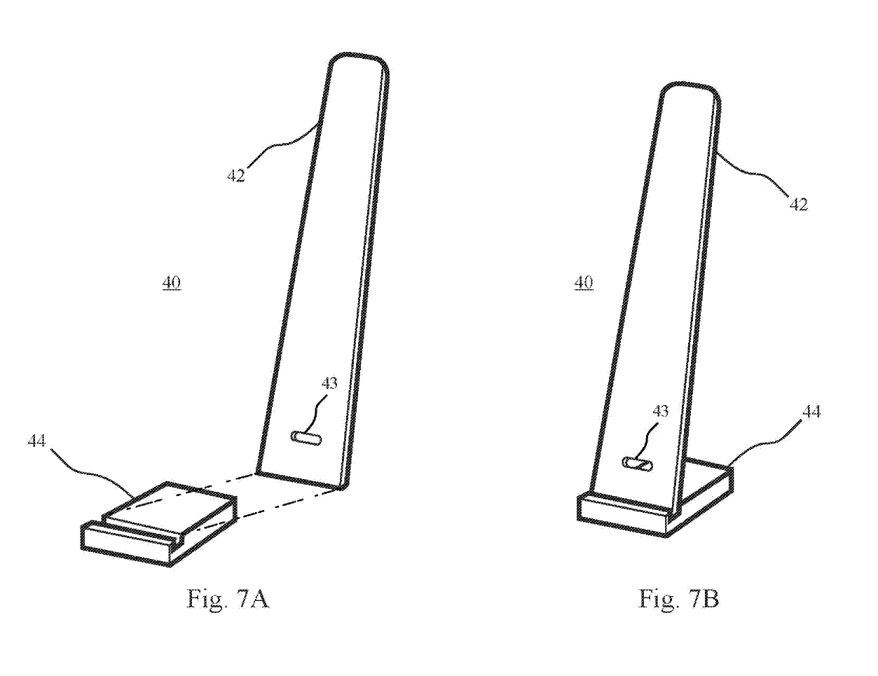

FIG. 7A shows base 44 having a slot for receiving angled vertical member 42 having hole 43 for allowing cables to be neatly configured.

FIG. 7B shows angled vertical member 42 inserted in base 44, thereby forming stand 40.

It will be appreciated that the detachability of angled vertical member 42 from base 44 makes it easier to ship and/or store stand 40.

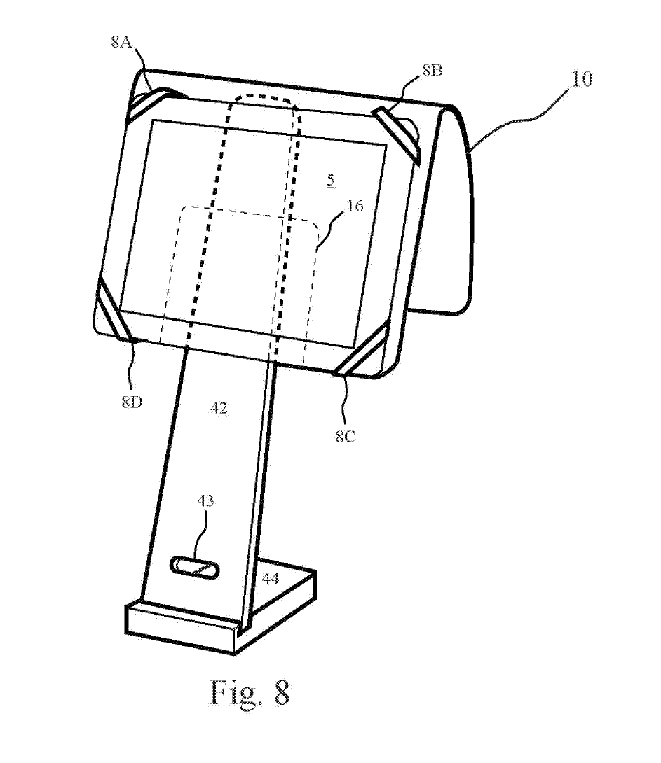

FIG. 8 shows a front three-dimensional view of stand 40 used with sleeve system 10 holding electronic device 5 in landscape orientation. Here, angled vertical member 42 is inserted into pocket 12 in place of a user's hand, and supports electronic device at generally eye level of a user. It will be appreciated that a user can easily slide sleeve system 10 whilst angled vertical member 42 remains in pocket 12, to change electronic device 5 from landscape orientation to portrait orientation and vice-versa.

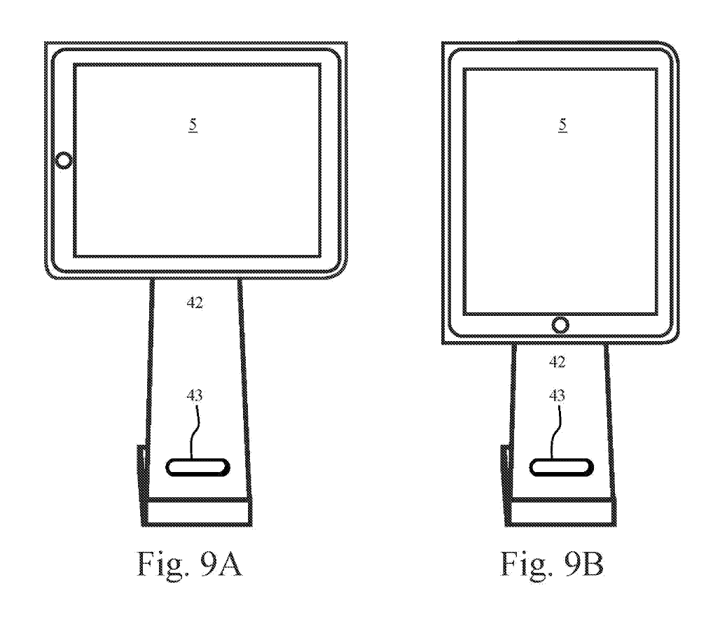

FIG. 9A shows a front view of stand 40 used with sleeve system 10 holding electronic device 5 in landscape orientation.

FIG. 9B shows a front view of stand 40 used with sleeve system 10 holding electronic device 5 in portrait orientation.

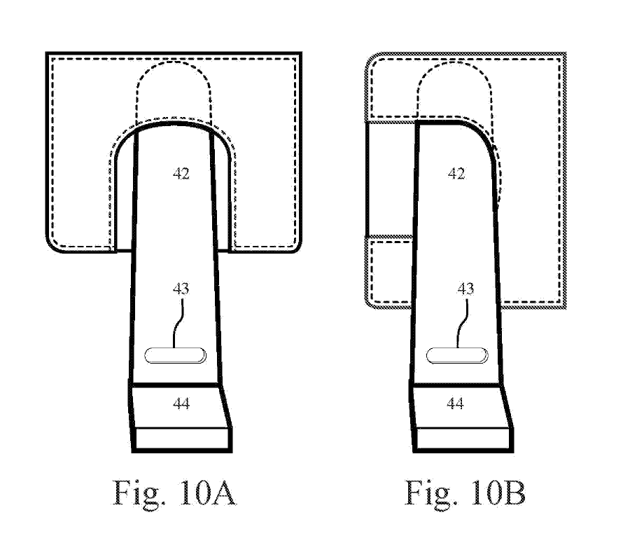

FIG. 10A shows a back view of stand 40 used with sleeve system 10 holding electronic device 5 in landscape orientation.

FIG. 10B shows a back view of stand 40 used with sleeve system 10 holding electronic device 5 in portrait orientation.

Another embodiment of the present invention directed to a wall hook for use with sleeve system 10 will now be described.

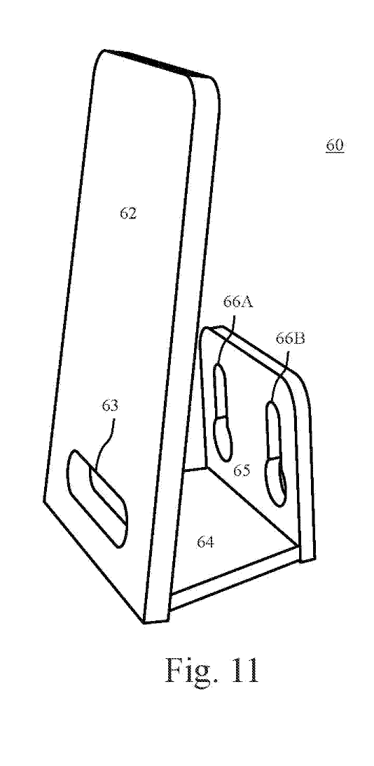

FIG. 11 shows a three-dimensional view of wall hook 60 having angled vertical member 62 with hole 63 for allowing a cable to be neatly configured. Angled vertical member 62 is attached to horizontal base 64 at one side of base 64. At the opposite side of base 64, vertical member 65 is attached, forming a generally U-shaped configuration with members 62, 65 being the arms of the U-shape and base 64 being the base of the U-shape. Vertical member 65 has openings 66A and 66B for receiving the arms of screws or nails, enabling wall hook 60 to be attached to a wall or other vertical surface.

It will be appreciated that a user can easily slide sleeve system 10 whilst angled vertical member 62 remains in pocket 12, to change electronic device 5 from landscape orientation to portrait orientation and vice-versa.

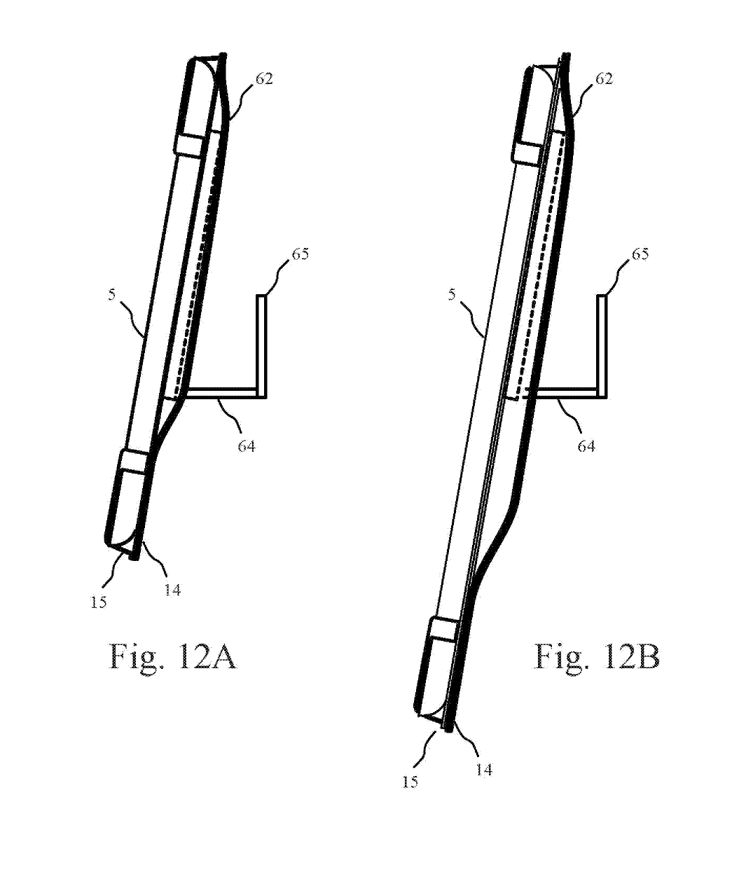

FIG. 12A shows a side view of wall hook 60 used with sleeve system 10 holding electronic device 5 in landscape orientation.

FIG. 12B shows a side view of wall hook 60 used with sleeve system 10 holding electronic device 5 in portrait orientation.

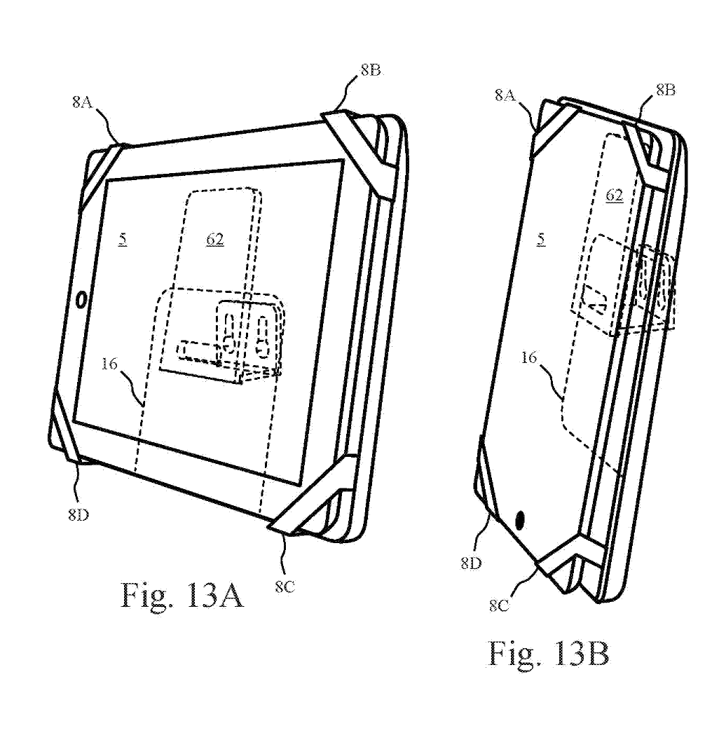

FIG. 13A shows a three-dimensional view of wall hook 60 used with sleeve system 10 holding electronic device 5 in landscape orientation.

FIG. 13B shows a three-dimensional view of wall hook 60 used with sleeve system 10 holding electronic device 5 in portrait orientation.

Various fastener types for fastening the vertical members of wall hook 60 to its base may include, but are not limited to: velcro, buttons, snaps, zipper, screws, glue, magnets, putty, tape, adhesive, and/or bolts.

Another embodiment of the present invention directed to a rail for use with a plurality of wall hooks for engaging with respective instances of sleeve system 10 will now be described. This embodiment allows the tablet device to act as a photo frame/picture that is dynamic and can be displayed in either a portrait or landscape configuration to provide rotatable displays (comprising of artwork, digital images, etc.)

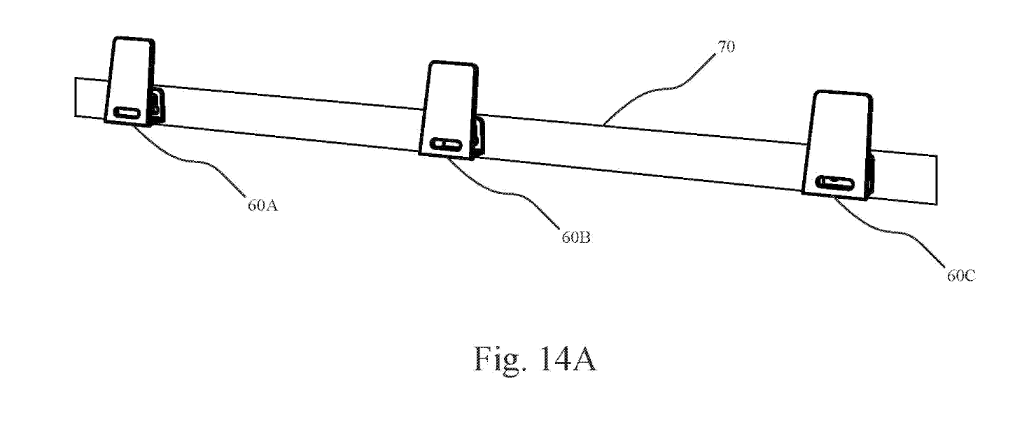

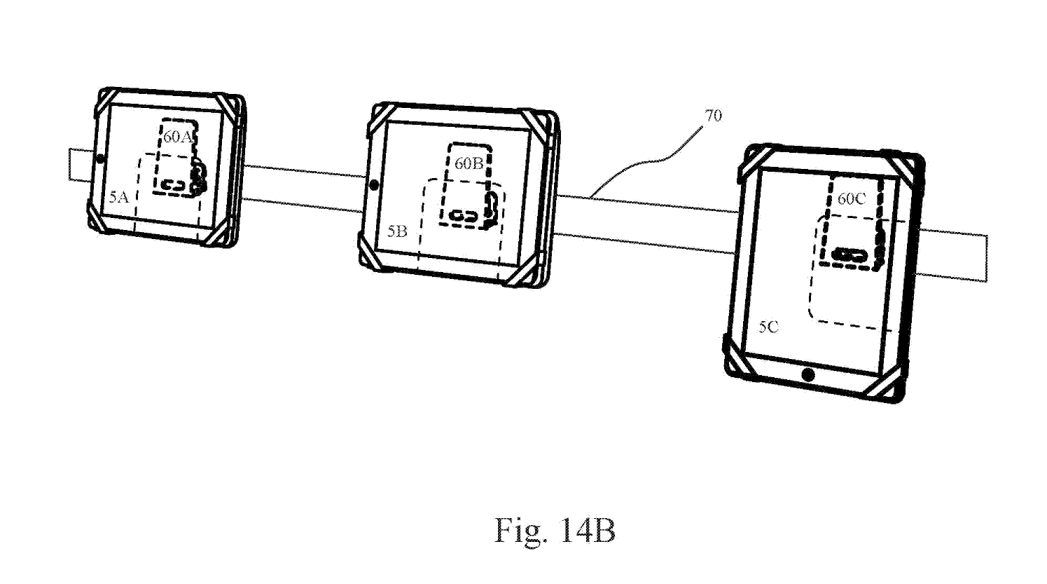

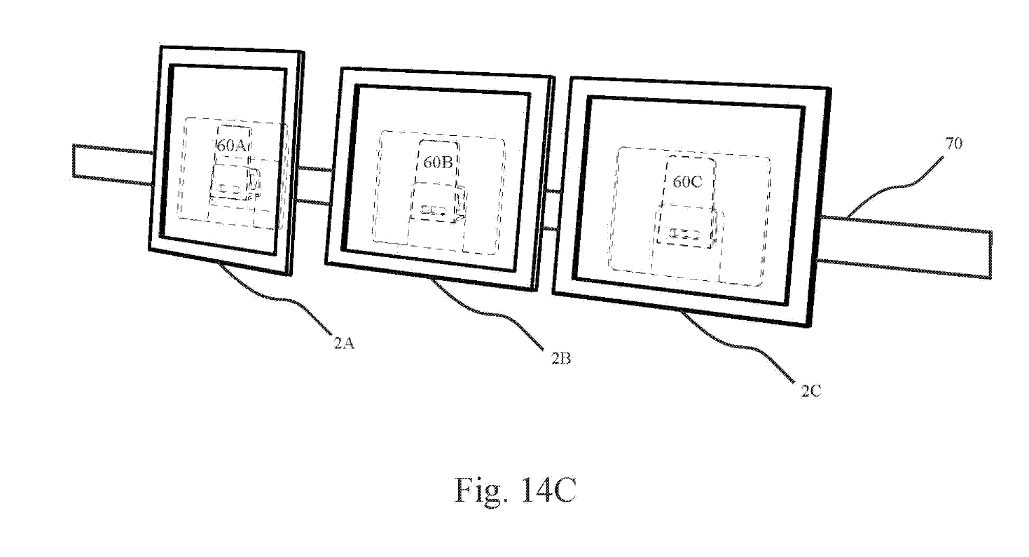

FIG. 14A shows a three-dimensional view of rail 70 with wall hooks 60A, 60B and 60C coupled to rail 70. Rail 70 is generally horizontal and may be made of any suitable material such as metal, plastic (opaque or transparent), or wood. Various fastener types for fastening wall hooks 60A, 60B, 60C to rail 70 may include, but are not limited to: Velcro, buttons, snaps, zipper, screws, glue, magnets, putty, tape, adhesive, and/or bolts.

FIG. 14B shows a three-dimensional view of rail 70 having wall hooks 60A, 60B, 60C respectively supporting sleeve systems 10A, 10B, 10C holding electronic devices 5A, 5B, 5C.

It will be appreciated that a user can easily slide sleeve systems 10A, 10B, 10C whilst the angled vertical member of wall hooks 60A, 60B, 60C remains in pocket 12, to change electronic devices 5A, 5B, 5C from landscape orientation to portrait orientation and vice-versa.

FIG. 14C shows a three-dimensional view of rail 70 having wall hooks 60A, 60B, 60C respectively supporting picture frames 2A, 2B and 2C. When a user prefers to have their electronic devices employed away from rail 70, rail 70 can still function to hold picture frames. When the picture frames have pockets on their backs, the pictures can readily be turned from landscape orientation to portrait orientation, perhaps to startle a viewer.

Another embodiment of the present invention directed to a handheld case will now be described.

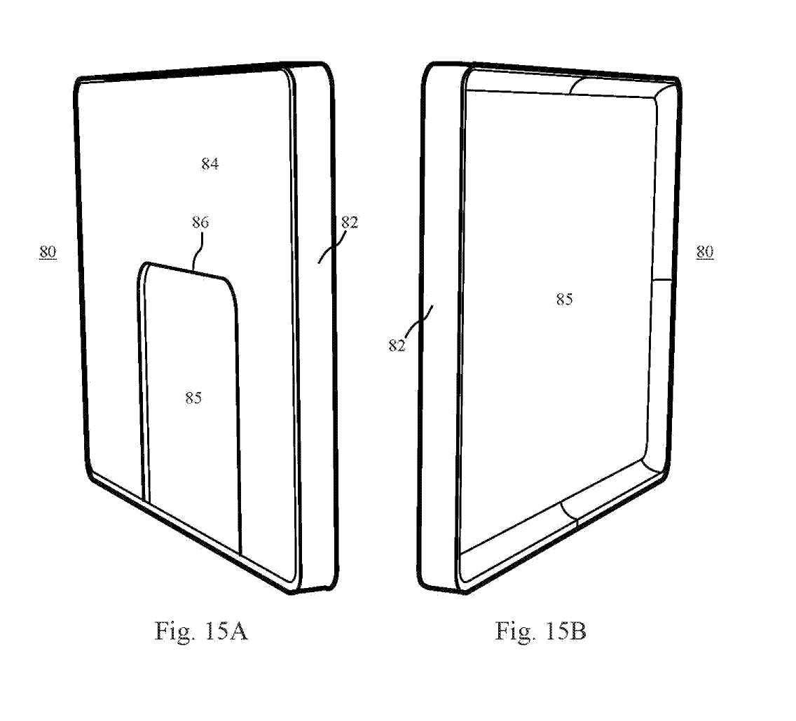

FIG. 15A shows a three-dimensional back view of sleeve system 80, which is a hardshell version of sleeve system 10. Back panel 85 has U-shaped cutout 86 along one side. A vertical member of stand 40, stand 50 or wall hook 60 is inserted into pocket 81 formed between back panel 84 and front panel 85.

FIG. 15B shows a three-dimensional front view of sleeve system 80, having edge 82 around the perimeter of front panel 85. Since front panel 85 is formed of a hard material, such as plastic or metal, an electronic device can be “snapped” into the well formed on the front of front panel 85.

In one variation, back panel 84 is formed of the same material as front panel 85. In another variation, back panel 84 is formed of a more flexible material to enable a user's hand to be inserted in pocket 81.

Another embodiment of the present invention directed to a garment for use with sleeve system 10 or 80 will now be described.

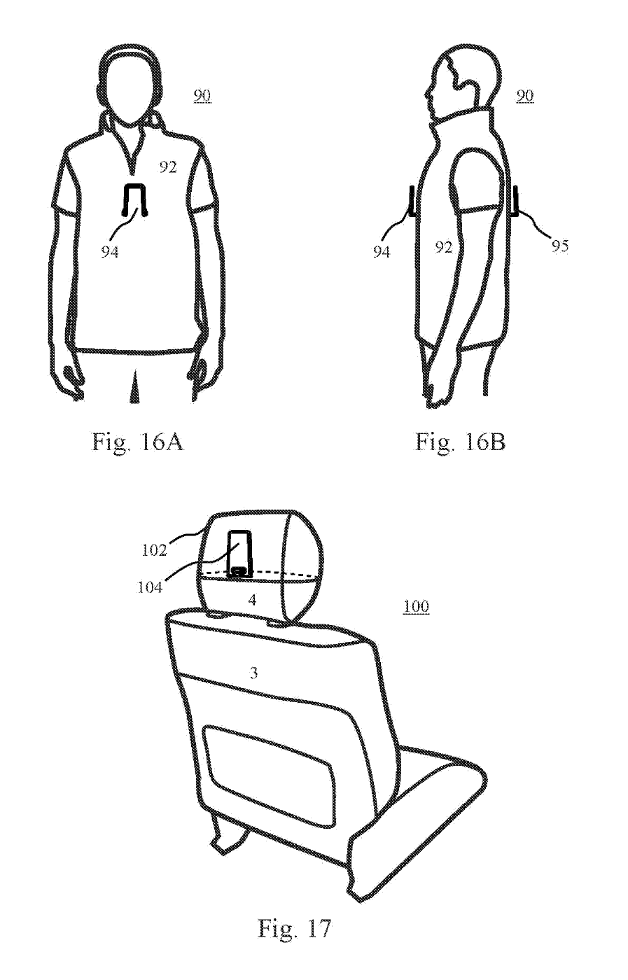

FIG. 16A shows a front view of vest 90 having main piece 92 with rigid vertical member 94 affixed to the front thereof. Vertical member 30 slides into pocket 12 of sleeve system 10 or pocket 81 of sleeve system 80, such that the wearer can display an electronic device in either the portrait orientation or the landscape orientation, and can easily switch orientations, to function as a portable billboard for brand promotion, advertising, or marketing.

FIG. 16B shows a side view of vest 90 showing that rigid vertical member 95 is affixed to the back thereof, and functions in similar manner as rigid vertical member 94.

In a variation, instead of being a vest, the garment may be a shirt or a necklace.

In another variation, a vertical member is attached to only one of the front and back of the garment.

In a further variation, multiple vertical members are attached to the front and/or the back of the garment.

Another embodiment of the present invention directed to a headrest cover for use with sleeve system 10 or 80 will now be described.

FIG. 17 shows a three-dimensional back view of seat rest cover 100 having main piece 102 with rigid vertical member 104 attached thereto. Main piece 102 fits over headrest 4 coupled to seat 3, which is a seat in a vehicle such as a car, bus, train or airplane. Vertical member 104 slides into pocket 12 of sleeve system 10 or pocket 81 of sleeve system 80, creating an in-vehicle video system. The present disclosure also contemplates the tablet device having an integrated audio sound system, or pairing or integrating with an existing sound system in a vehicle (or with headphones) either wired or wirelessly, such as through Bluetooth.

The present invention contemplates the mounting of a plurality of different devices, products, and equipment on any of the receiving systems described herein such as, but not limited to: clocks, signage, picture frames, albums, diplomas, awards, artwork, and the like.

Although illustrative embodiments of the present invention, and various modifications thereof, have been described in detail herein with reference to the accompanying drawings, it is to be understood that the invention is not limited to these precise embodiment and the described modifications, and that various changes and further modifications may be effected therein by one skilled in the art without departing from the scope or spirit of the invention as defined in the appended claims.

What is claimed is:

1. A system for displaying a display device comprising:
a housing with a means for receiving the display device and a pocket/sleeve on a back side of the housing, the pocket sleeve having a teeth opening shape;
wherein the teeth opening shape allows a user to have a plurality of positions within that pocket to enable the user to rotate the device from a horizontal to a vertical view without removing their hand from the pocket/sleeve.

2. The system of claim 1 further comprising a stand, wherein the stand receives the system in the pocket sleeve.

3. The system of claim 1 further comprising a wall mount system, wherein the wall mount system receives the system in the pocket sleeve to enable a plurality of different orientations.
